(19) United States
(12) Patent Application Publication
(10) Pub. No.: US 2025/0079856 A1
(43) Pub. Date: Mar. 6, 2025

(54) SYSTEM AND METHOD FOR CHARGING CONTROL BETWEEN BATTERY PACKS

(71) Applicant: LG ENERGY SOLUTION, LTD., Seoul (KR)

(72) Inventors: Kee Hoon SONG, Daejeon (KR); Jun Suk KIM, Daejeon (KR); Hyo Seong AN, Daejeon (KR)

(73) Assignee: LG ENERGY SOLUTION, LTD., Seoul (KR)

(21) Appl. No.: 18/579,690

(22) PCT Filed: Dec. 20, 2022
(86) PCT No.: PCT/KR2022/020850

§ 371 Date: Jan. 16, 2024

(30) Foreign Application Priority Data
Jun. 7, 2022 (KR) 10-2022-0068958

(51) Int. Cl. H02J 7/00

(52) U.S. Cl. CPC H02J 7/0024; H02J 7/0019; H02J 7/0048

(57) ABSTRACT

The present invention relates to a serial battery pack-to-pack charging control system and a method thereof, and to a series battery pack-to-pack charging control system configured such that a battery pack having a higher voltage can charge a battery pack having a lower voltage so as to reduce the SOC difference between the two battery packs when a voltage difference between two battery packs is large in a state where battery packs are stored in a system by being connected thereto.

### TECHNICAL FIELD

The present invention relates to a battery pack-to-pack charging control system and a method thereof, and more particularly, to a series battery pack-to-pack charging control system capable of reducing a state of charge (SOC) difference between series battery packs connected to an external system, and a method thereof.

### BACKGROUND ART

A battery is used in various fields, including an electric scooter, electric vehicle, energy storage capacitor, etc., as well as a portable electronic device, such as a smart phone, notebook computer, and tablet PC. A field such as an electrically driven vehicle or smart grid system often requires large capacity, and thus a plurality of battery packs are used by being connected in series in order to increase output.

Generally, in a light electric vehicle (LEV), such as an electric bicycle or an electric scooter, two battery packs are configured to be used in series. In this case, when SOCs of the two battery packs are not the same, discharging is terminated when the SOC of the battery pack having a lower SOC reaches 0% during driving, and driving is terminated at that time.

Therefore, in this way, since a driving distance is calculated and the system is controlled based on the battery pack having the lower SOC, when two battery packs having a large SOC difference are used, the system is controlled based on the battery pack having the lower SOC, and thus there is a problem in that inconvenience and anxiety occur to a user due to an unexpected short driving distance.

In this regard, when reviewing Japanese unexamined patent application publication No. JP 2013-240219 A, a technical idea of performing parallel stabilization before use of the battery in order to equalize the capacity of two battery blocks connected in series has been suggested, but a technology of performing series/parallel switching according to the usage condition of the battery has not been suggested.

As prior art related to the present invention, there is a following document.

Japanese unexamined patent application publication No. JP 2013-240219 A

### DISCLOSURE OF THE INVENTION

### Technical Problem

The present invention is intended to solve the problems described above, and is configured to reduce the SOC difference between battery packs by allowing a battery pack having a higher SOC to charge a battery pack having a lower SOC when the battery packs are connected to the system and the difference in remaining capacity (SOC) between the two battery packs is large in a standby state.

### Technical Solution

In order to solve the problems described above, the present invention provides a series battery pack-to-pack charging control system configured to include a first battery pack, a second battery pack, and a battery connection unit, in which the battery connection unit connects the first and second battery packs in parallel and cuts off an output to an external system when the external system is in a standby state, and connects the first and second battery packs in series and outputs a series connection output thereof to the external system when the external system is in an active state.

In this case, the battery connection unit may be configured to include an input unit that receives outputs of the first and second battery packs, an output unit that outputs or blocks the outputs of the first and second battery packs input to the input unit to the external system, and a path connection unit that constitutes connection of the first and second battery packs between the input unit and the output unit.

In addition, the input unit may be configured to include a first (+) connection part connected to a (+) terminal of the first battery pack, a second (+) connection part connected to a (+) terminal of the second battery pack, a first (−) connection part connected to a (−) terminal of the first battery pack, a second (−) connection part connected to a (−) terminal of the second battery pack, and the path connection unit may be configured to include a first path connecting the first (−) connection part and the second (−) connection part, a second path connecting the first (+) connection part and the second (+) connection part, a third path connecting the second (+) connection unit and a (+) output end, a fourth path connecting the first (+) connection part and the second (−) connection part, a fifth path connecting the first (−) connection unit and a (−) output end, and first to fifth switches opening and closing the first to fifth paths, respectively.

In this case, the external system acquires and compares pack SOCs for acquiring SOC values from the respective first and second battery packs at regular intervals, and, when the SOC difference exceeds a predetermined reference pack SOC difference, outputs a parallel switching signal to connect the first and second battery packs in parallel, thereby capable of tailoring the SOCs of the two battery packs. In addition, when the pack SOC difference is within the predetermined reference SOC difference, the parallel connection of the first and second battery packs is switched to a series connection.

### Advantageous Effects

According to an embodiment of the present invention, when the state of charge (SOC) difference between two battery packs exceeds the standard in a state where the batteries are stored in the system by being connected thereto, the battery pack having the higher SOC charges the battery pack having the lower SOC, thereby capable of reducing the SOC difference between the two battery packs. Accordingly, since the actual driving distance of the system increases, user convenience can be increased.

### BRIEF DESCRIPTION OF THE DRAWINGS

FIG. 1 is a diagram illustrating an overall configuration of a system according to an embodiment of the present invention.

FIG. 2 is a diagram illustrating an operation in which a battery pack having a higher voltage charges a battery pack having a lower voltage according to the embodiment of the present invention.

FIG. 3 is a diagram illustrating a detailed configuration of a control unit according to the embodiment of the present invention.

FIG. 4 is a diagram illustrating a series battery pack-to-pack charging control method according to an embodiment of the present invention.

### MODES FOR CARRYING OUT THE INVENTION

Hereinafter, embodiments of the present invention will be described in detail with reference to the accompanying drawings so that those of ordinary skill in the art can easily carry out the present invention. However, the present invention may be embodied in various different forms and is not limited to the embodiments described herein. In order to clearly explain the present invention in the drawings, parts irrelevant to the description are omitted, and similar reference numerals are assigned to similar parts throughout the specification.

Hereinafter, the present invention will be described in detail with reference to the drawings.

### 1. Series Battery Pack-to-Pack Charging Control System According to the Present Invention

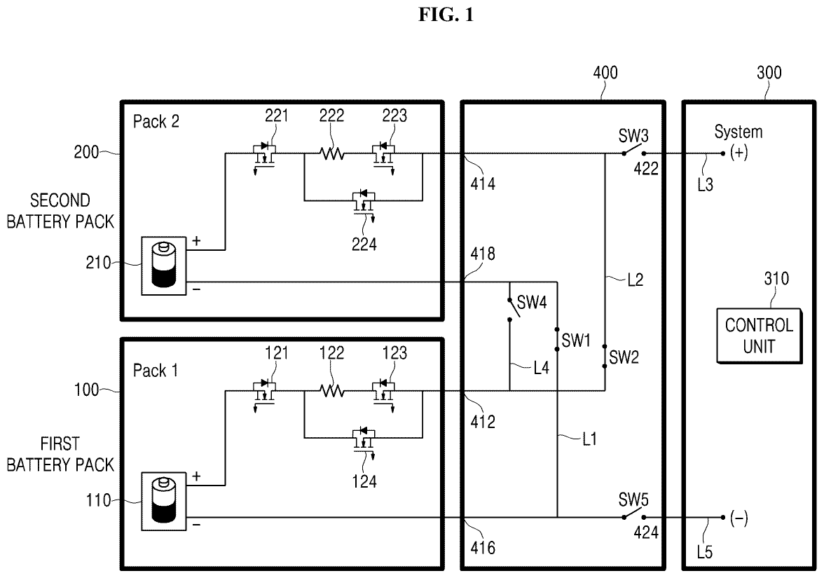

FIG. 1 is a diagram schematically illustrating the overall configuration of a series battery pack-to-pack charging control system according to an embodiment of the present invention.

Referring to FIG. 1, a system according to an embodiment of the present invention is configured to include the following configurations.

### 1. 1. Two or More Battery Packs

The system of the present invention includes two or more battery packs 100 and 200 connected in series with each other.

### 1. 1. 1. First Battery Pack 100

As illustrated in FIG. 1, the first battery pack 100 is configured to include a first battery cell module 110 and a first discharge circuit unit 120.

a. First Battery Cell Module 110

The first battery cell module 110 includes one or more battery cells (not illustrated), a first cell module (+) terminal, and a first battery cell module (−) terminal.

b. First Discharge Circuit Unit 120

The first discharge circuit unit 120 (121, 122, 123, and 124) refers to a current path configured between the first battery cell module 110 and a battery connection unit 400 to be described later. More specifically, it is formed on a path connecting the first cell module (+) terminal of the first battery cell module 110 and a first battery pack (+) terminal.

### 1) First Discharge FET (D-FET) 121

The first discharge FET (D-FET) 121 is disposed in series between the first cell module (+) terminal and a first discharge resistor 122.

The first discharge FET (D-FET) 121 is turned on by a switching control unit 318 of a control unit 310 to be described later when an external system 300 connected to the first and second battery packs 100 and 200 in which the SOC of the second battery pack 200 is greater than that of the first battery pack 100 is in a standby state, that is, when a user does not use the external system 300,

### 2) First Discharge Resistor 122

The first discharge resistor 122 is disposed in series between the first discharge FET (D-FET) 121 and a first pre-charge FET (pre-FET) 123. The first discharge resistor 122 disposed in this way performs a function of limiting an amount of charging current flowing from the first battery pack 100 to the second battery pack 200 when a voltage of the first battery pack 100 is higher than that of the second battery pack 200.

### 3) First Precharge FET (P-FET) 123

The first precharge FET (P-FET) 123 is disposed in series with the first discharge resistor 122 and the first cell module (+) terminal.

### 4) First Charge FET (C-FET) 124

The first charge D-FET 124 is disposed in series between an output of the first discharge FET (D-FET) 121 and the first cell module (+) terminal, and is disposed in parallel to a series connection of the first discharge resistor 122 and the first discharge precharge FET (P-FET) 123.

### 1. 1. 2. Second Battery Pack 200

As illustrated in FIG. 1, the second battery pack 200 includes a second battery cell module 210 and a second discharge circuit unit 220.

a. Second Battery Cell Module 210

The second battery cell module 210 includes one or more battery cells (not illustrated), a second cell module (+) terminal, and a second battery cell module (−) terminal.

b. Second Discharge Circuit Unit 220

The second discharge circuit unit 220 (221, 222, 223, and 224) refer to a current path configured between the second battery cell module 210 and the battery connection unit 400 to be described later. More specifically, it is formed on a path connecting the second cell module (+) terminal of the second battery cell module 210 and a second battery pack (+) terminal.

### 1) Second Discharge FET (D-FET) 221

The second discharge D-FET 221 is disposed in series between the first cell module (+) terminal and the first discharge resistor 222.

The second discharge FET (D-FET) 221 is turned on by the switching control unit 318 of the control unit 310 to be described later when the external system 300 connected to the first and second battery packs 100 and 200 in which the SOC of the first battery pack 100 is greater than that of the second battery pack 200 is in a standby state, that is, when the user does not use the external system 300.

### 2) Second Discharge Resistor 222

The second discharge resistor 222 is disposed in series between the second discharge D-FET 221 and the second discharge precharge FET (p-FET) 123. The second discharge resistor 222 disposed in this way performs a function of limiting an amount of charging current flowing from the second battery pack 200 to the first battery pack 100 when the voltage of the second battery pack 200 is higher than that of the first battery pack 100.

### 3) Second Discharge Precharge FET (P-FET) 223

The second discharge P-FET 223 is disposed in series with the second discharge resistor 222 and the second cell module (+) terminal.

### 4) Second Charge FET (C-FET) 224

The second charge FET (C-FET) 124 is disposed in series between an output of the second discharge FET 121 and the second cell module (+) terminal, and is disposed in parallel to the series connection of the second discharge resistor 222 and the second discharge P-FET 223.

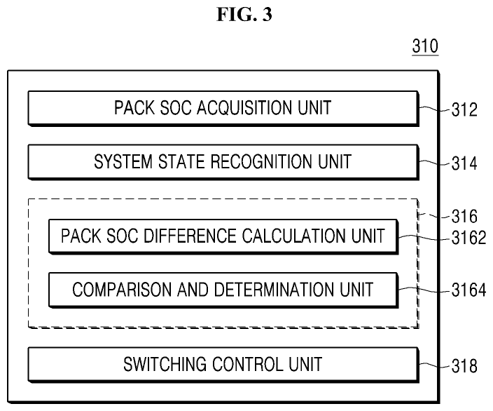

FIG. 3 is a diagram illustrating a detailed configuration of a control unit according to an embodiment of the present invention.

### 1. 2. Control Unit 310

The controller 310 is a configuration that controls charging between the first and second battery packs 100 and 200 according to a SOC difference between the first and second battery packs 100 and 200 in the standby state of the external system 300 connected to the first and second battery packs 100 and 200.

a. Pack SOC Acquisition Unit 312

The pack SOC acquisition unit 312 is a configuration that acquires SOC values from the respective first and second battery packs 100 and 200 at regular intervals. For acquisition or calculation of SOC, a known SOC calculation method is used.

b. System State Recognition Unit 314

The system state recognition unit 314 is a configuration that recognizes whether the external system 300 is in a standby state or an active state in a state of being connected to the first and second battery packs 100 and 200.

Here, the standby state refers to a state where the user does not use the external system 300 in a state where the first and second battery packs 100 and 200 and the external system 300 are connected.

On the other hand, the active state refers to a situation in which the user uses the external system 300 in the state where the first and second battery packs 100 and 200 are connected to the external system 300.

When it is recognized as being in the standby state, for example, a standby state signal can be output.

When it is recognized as being in the active state, for example, an active state signal can be output.

c. Whether-to-Switch-Connection Determination Unit 316

The whether-to-switch-connection determination unit 316 is a configuration that determines whether to switch a connection state between the battery packs according to the SOC difference between the first and second battery packs 100 and 200 when the standby state signal is output from the system state recognition unit 314.

The whether-to-switch-connection determination unit 316 may include the following detailed configurations.

### 1) Pack SOC Difference Calculation Unit 3162

The pack SOC difference calculation unit 3162 calculates a pack SOC difference, which is an SOC difference value between the first and second battery packs 100 and 200, using the SOC values of the respective first and second battery packs 100 and 200 acquired by the pack SOC acquisition unit 312.

### 2) Comparison and Determination Unit 3164

The comparison and determination unit 3164 compares whether the calculated pack SCO difference exceeds a predetermined reference pack SOC difference, and when it exceeds the SOC difference, determines that the connection state of the first and second battery packs 100 and 200 is switched to parallel connection. In the case of the determination, for example, a parallel switching signal indicating this may be output.

In addition, the comparison and determination unit 3164 determines that the connection state of the first and second battery packs 100 and 200 is switched to series connection when the pack SOC difference calculated by the pack SOC difference calculation unit 3162 is within a predetermined reference SOC difference after the parallel switching signal is output. In this case, a signal indicating this, for example, a serial switching signal may be output.

d. Switching Control Unit 318

The switching control unit 318 is a configuration that controls opening and closing of first to fifth switches SW1 to SW5 configured in the battery connection unit 400 to be described later.

Specifically, when the parallel switching signal is output from the whether-to-switch-connection determination unit 316, it turns off the third, fourth, and fifth switches SW3, SW4, and SW5 to open third, fourth, and fifth paths L3, L4, L5 and turns on the first and second switches SW1 and SW2 to close first and second paths L1 and L2, thereby connecting the first and second battery packs 100 and 200 to each other.

Accordingly, the output to the external system 300 may be cut off, and the battery pack having the higher SOC among the first and second battery packs 100 and 200 may be allowed to charge the battery pack having the lower SOC.

On the other hand, when the serial switching signal is output from the whether-to-switch-connection determination unit 316 or an active signal is output from the system state recognition unit 314, it turns on the third, fourth, and fifth switches SW3, SW4, and SW5 to close the third, fourth, and fifth paths L3, L4, and L5, and turns off first and second switches SW1 and SW2 to open the first and second paths L1 and L2, thereby connecting the first and second battery packs 100 and 200 in series with each other. Accordingly, the series connection output of the first and second battery packs 100 and 200 is supplied to the external system 300.

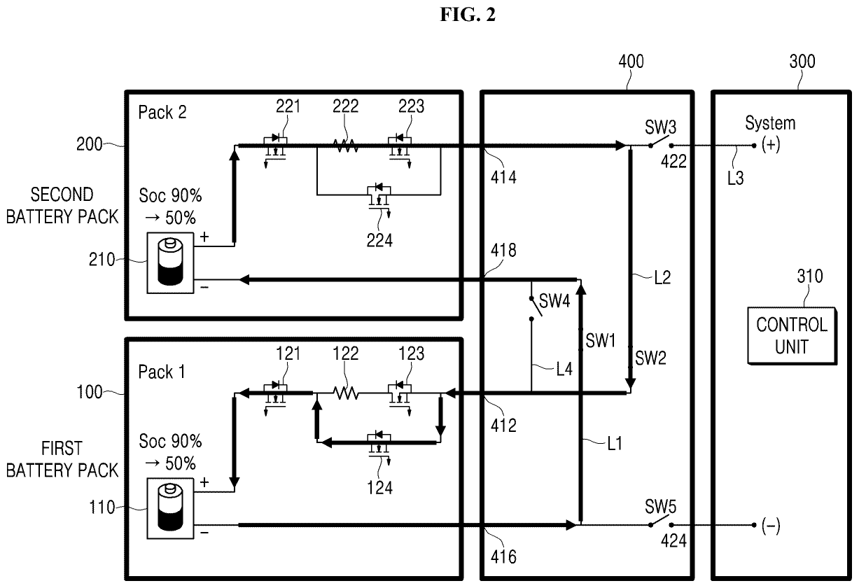

FIG. 2 is a diagram illustrating an operation in which a battery pack having a higher SOC charges a battery pack having a lower SOC according to an embodiment of the present invention.

Referring to FIG. 2, for example, when the SOC difference between the first and second battery packs 100 and 200 exceeds the predetermined reference SOC difference and the SOC of the second battery pack 200 is higher than that of the first battery pack 100, the third, fourth, and fifth switches SW3, SW4, and SW5 are turned off to open the third, fourth, and fifth paths L3, L4, and L5, and the first and second switches SW1 and SW2 are turned on to close the first and second paths L1 and L2, thereby connecting the first and second battery packs 100 and 200 in parallel to each other.

In addition, the second charge FET (C-FET) 224 is turned off, the second discharge FET (D-FET) 221 and the second discharge P-FET 223 are turned on, and the first charge FET 124 is turned on to allow the current of the second battery cell module 210 to flow into the first battery cell module 110 to charge it, thereby capable of eliminating the SOC difference between the battery packs 100 and 200.

In contrast, when the SOC of the second battery pack 200 is lower than the SOC of the first battery pack 100, in the same manner, the first and second battery packs are connected in parallel, the first discharge D-FET 121 is turned on, and the first discharge P-FET 123 of the first battery pack and the second charge FET 224 of the second battery pack are turned on to allow the current of the first battery cell module 110 to flow into the second battery cell module 210 to charge it, thereby capable of eliminating the SOC difference between the battery packs 100 and 200.

The control unit 310 as described above may be implemented in the external system 300, and may control opening and closing of the transistors 121, 123, 124, 221, 223, and 224 by transmitting a control signal to BMS (not illustrated) of the first and second battery packs.

Here, the external system 300 refers to a LEV device including, for example, an electric bicycle, an electric scooter, etc.

### 1. 3. Battery Connection Unit 400

When the external system 300 connected to the first and second battery packs 100 and 200 is in the standby state, the battery connection unit 400 connects the first and second battery packs 100 and 200 in parallel according to a control signal from the control unit 310 and cuts off an output to the external system 300.

On the other hand, when the external system 300 connected to the first and second battery packs 100 and 200 is in the active state, the battery connection unit 400 connects the first and second battery packs 100 and 200 in series according to the control signal from the control unit 310 and outputs the series connection output thereof to the external system 300.

This battery connection unit 400, includes the following detailed configurations as illustrated in FIG. 1.

a. Input Unit 410

The input unit is a configuration that receives outputs of the first and second battery packs 100 and 200.

### 1) First (+) Connection Part 412

The first (+) connection part is connected to a (+) terminal of the first battery pack 100.

### 2) Second (+) Connection Part 414

The second (+) connection part is connected to a (+) terminal of the second battery pack 200.

### 3) First (−) Connection Part 416

The first (−) connection part is connected to a (−) terminal of the first battery pack 100.

### 4) Second (−) Connection Part 418

The second (−) connection part is connected to a (−) terminal of the second battery pack 200.

b. Output Unit 420

The output unit is a configuration that outputs or cuts off the output of the first and second battery packs 100 and 200, which is input to the input unit, to the external system 300.

### 1) (+) Output End 422

The (+) output end connects a (+) output of the first and second battery packs 100 and 200 in series to the external system 300.

### 2) (−) Output End 424

The (−) output end connects a (−) output of the first and second battery packs 100 and 200 in series to the external system 300.

c. Path Connection Unit 400

The path connection unit 400 configures the connection of the first and second battery packs 100 and 200 between the input unit and the output unit, and includes the following detailed configurations.

### 1) First Path L1

The first path L1 is a path connecting the first (−) connection part 416 and the second (−) connection part 418, and is opened and closed by the first switch SW1.

### 2) Second Path L2

The second path L2 is a path connecting the first (+) connection part 412 and the second (+) connection part 414, and is opened and closed by the second switch SW2.

### 3) Third Path (L3)

The third path L3 is a path connecting the second (+) connection part 414 and the (+) output end 422, and is opened and closed by the third switch SW3.

### 4) Fourth Path L4

The fourth path L4 is a path connecting the first (+) connection part 412 and the second (−) connection part 418, and is opened and closed by the fourth switch SW4.

### 5) Fifth Path L5

The fifth path L5 is a path connecting the first (−) connection part 416 and the (−) output end 424, and is opened and closed by the fifth switch SW5.

### 6) First Switch SW1

The first switch SW1 is configured on the first path L1, and is turned on/off according to the control of the switching control unit 318 of the control unit 310 to open and close the first path L1.

### 7) Second Switch SW2

The second switch SW2 is configured on the second path L2, and is turned on/off according to the control of the switching control unit 318 of the control unit 310 to open and close the second path L2.

### 8) Third Switch SW3

The third switch SW3 is configured on the third path L3, and is turned on/off according to the control of the switching control unit 318 of the control unit 310 to open and close the third path L3.

### 9) Fourth Switch SW4

The fourth switch SW4 is configured on the fourth path L4, and is turned on/off according to the control of the switching control unit 318 of the control unit 310 to open and close the fourth path L4.

### 10) Fifth Switch SW5

The fifth switch SW5 is configured on the fifth path L5 and is turned on/off according to the control of the switching control unit 318 of the control unit 310 to open and close the fifth path L5.

### 2. Series Battery Pack-to-Pack Charging Control Method According to the Present Invention

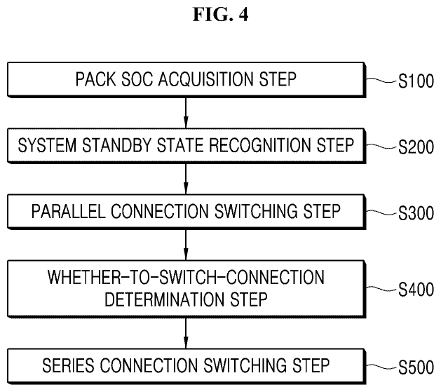

FIG. 4 is a diagram illustrating a series battery pack-to-pack charging control method according to an embodiment of the present invention.

Referring to FIG. 4, in the method according to an embodiment of the present invention, in a state where two or more battery packs connected in series are connected to/mounted in an external system (e.g., electric bicycle, electric scooter, etc.), depending on a state of the SOC difference between the battery packs and whether or not the external system is in a standby state, the SOC difference can be eliminated through serial/parallel connection switching between the battery packs. This method includes the following steps.

### 2. 1. Pack SOC Acquisition Step S100

The pack SOC acquisition step S100 is a step in which the control unit 310 acquires the SOC values of the respective series battery packs 100 and 200 at regular intervals.

More specifically, in the configuration of the controller 310 implemented in the external system 300 connected to the series battery packs 100 and 200, respective SOC values may be acquired at regular intervals through a communication connection with the battery packs 100 and 200.

### 2. 2. System Standby State Recognition Step S200

The system standby state recognition step S200 is a step of recognizing whether the external system 300 is in a standby state in a state of being connected to the serial battery packs 100 and 200.

Specifically, in a state where the serial battery packs 100 and 200 and the external system 300 are connected, the control unit 310 implemented in the external system 300 can recognize whether the external system 300 is in the standby state.

Here, the standby state refers to a situation in which the external system 300 does not use the series output of the battery packs 100 and 200 in a state where the first and second battery packs 100 and 200 and the external system 300 are connected.

On the other hand, the active state is a non-standby state, and refers to a situation in which the external system 300 is driven by the series output of the battery packs 100 and 200 in a state where the first and second battery packs 100 and 200 are connected to the external system 300,

### 2. 3. Parallel Connection Switching Step S300

The parallel connection switching step is a step of switching a connection state between the battery packs according to the SOC difference between the first and second battery packs 100 and 200 when the external system 300 is recognized as being in the standby state as a result of the recognition in the system standby state recognition step S200.

a. First Pack SOC Difference Calculation Step

The first pack SOC difference calculation step is a step of calculating a SOC difference between the battery packs using the SOC values of the respective first and second battery packs 100 and 200 acquired in the pack SOC acquisition step S100 when the external system 300 is recognized as being in the standby state in the system standby state recognition step S200,

b. First Comparison and Determination Step

The first comparison and determination step is a step of comparing whether the SOC difference between the first and second battery packs 100 and 200 calculated in the first pack SOC difference calculation step exceeds a predetermined reference pack SOC difference and determining that the series connection of the battery packs 100 and 200 is switched to the parallel connection according to the comparison result.

More specifically, as a result of the comparison, when the SOC difference between the first and second battery packs 100 and 200 exceeds the predetermined reference pack SOC difference, it is determined that the series connection of the battery packs 100 and 200 is switched to the parallel connection, and the connection thereof is switched to the parallel connection.

That is, when the parallel connection switching determination is made in the first comparison and determination step, the parallel connection switching is performed.

Referring to FIG. 1, this may be implemented in a form of connecting the first and second battery packs 100 and 200 in parallel to each other by turning off the third, fourth, and fifth switches SW3, SW4, and SW5 of the battery connection unit 400 configured between the first and second battery packs 100 and 200 and the external system 300 to open the third, fourth, and fifth paths L3, L4, and L5 and turning on the first and second switches SW1 and SW2 to close the first and second paths L1 and L2.

Through these steps, the first and second battery packs 100 and 200 are connected in parallel, and thus, as illustrated in FIG. 2, a current is allowed to flow from a battery pack having a higher SOC to a battery pack having a lower SOC among the first and second battery packs 100 and 200 to charge the battery pack, so that the SOC difference between the battery packs can be eliminated.

### 2. 4. Whether-to-Switch-Connection Determination Step S400

The whether-to-switch-connection determination step S400 is a step of determining that the parallel connection of the first and second battery packs is switched to the series connection according to whether the SOC difference between the first and second battery packs 100 and 200 is within the predetermined reference pack SOC difference after the parallel connection switching in the parallel connection switching step S300.

a. Second Pack SOC Difference Calculation Step

The second pack SOC difference calculation step is a step of calculating the pack SOC difference using the SOC values of the respective first and second battery packs 100 acquired through the pack SOC acquisition step S100 after the first and second battery packs 100 and 200 are connected in parallel in the parallel connection switching step S300.

b. Second Comparison and Determination Step

The second comparison and determination step is a step of comparing whether the SOC difference between the first and second battery packs 100 and 200 calculated in the first pack SOC difference calculation step is within the predetermined reference pack SOC difference and determining that the parallel connection of the battery packs 100 and 200 is switched to the series connection when it is within the predetermined reference pack SOC difference.

### 2. 5. Series Connection Switching Step S500

The series connection switching step S500 is a step of switching the parallel connection of the first and second battery packs 100 and 200 to the series connection when it is determined, in the whether-to-switch-connection determination step S400, that the parallel connection of the first and second battery packs 100 and 200 is switched to the series connection.

Referring to FIG. 1, this may be implemented in a form of connecting the first and second battery packs 100 and 200 in series with each other by turning on the third, fourth, and fifth switches SW3, SW4, and SW5 of the battery connection unit 400 configured between the first and second battery packs 100 and 200 and the external system 300 to close the third, fourth, and fifth paths L3, L4, and L5 and turning off the first and second switches SW1 and SW2 to open the first and second paths L1 and L2.

As such, when the SOC difference between the series battery packs 100 and 200 is large in a state where the battery packs 100 and 200 are stored in the external system 300 by being connected thereto, the SOC difference between the battery packs can be eliminated by connecting the battery packs in parallel to each other through control of the switches configured between the battery packs and the external system 300 to allow the battery pack having a higher SOC to charge the battery pack having a lower SOC. Accordingly, the usability and efficiency of the external system 300 may be improved by maximizing the time available for serial output of the first and second battery packs 100 and 200.

Meanwhile, although the technical idea of the present invention has been described in detail according to the above embodiments, it should be noted that the above embodiments are for description and not for limitation. In addition, those skilled in the art will understand that various embodiments are possible within the scope of the technical spirit of the present invention.

The names for the symbols used in the drawings of this invention are as follows.
100, 200: first battery pack, second battery pack
120, 220: first discharge circuit unit, second discharge circuit unit
121, 221: first discharge FET, second discharge FET
122, 222: first discharge resistor, second discharge resistor
123, 223: first discharge P-FET, second discharge P-FET
124, 224: first charge FET, second charge FET
300: external system
310: control unit
312: pack SOC acquisition unit
314: system state recognition unit
316: whether-to-switch-connection determination unit
3162: pack SOC difference calculation unit
3164: comparison and determination unit
318: switching control unit
400: battery connection unit

1. A battery pack-to-pack charging control system, comprising:
a first battery pack;
a second battery pack; and
a battery connector configured to:
connect the first and second battery packs in parallel and cut off an output to an external system when the external system is in a standby state, and
connect the first and second battery packs in series and output a series connection output of the first and second battery packs to the external system when the external system is in an active state.

2. The system of claim 1, wherein the battery connector comprises:
an input configured to receive outputs of the first and second battery packs,
an output configured to output or block the received outputs of the first and second battery packs to the external system, and
a path connector configured to provide a connection of the first and second battery packs between the input and the output of the battery connector.

3. The system of claim 2, wherein:
the input comprises:
a first (+) connection part connected to a (+) terminal of the first battery pack,
a second (+) connection part connected to a (+) terminal of the second battery pack,
a first (−) connection part connected to a (−) terminal of the first battery pack, and
a second (−) connection part connected to a (−) terminal of the second battery pack, and
the path connector comprises:
a first path connecting the first (−) connection part and the second (−) connection part,
a second path connecting the first (+) connection part and the second (+) connection part,
a third path connecting the second (+) connection unit and a (+) output end,
a fourth path connecting the first (+) connection part and the second (−) connection part,
a fifth path connecting the first (−) connection unit and a (−) output end, and
first to fifth switches configured to open and close the first to fifth paths, respectively.

4. The system of claim 3, wherein;
the first and second battery packs respectively comprise first and second discharge circuits in a path connecting a (+) terminal of a cell module and a pack (+) terminal, and the first and second discharge circuits respectively comprise:
a discharge FET, a discharge resistor, and a discharge precharge FET connected in series to the discharge FET; and
a charge FET connected in parallel to the resistor and the discharge precharge FET connected in series to the discharge FET.

5. The system of claim 4, wherein the external system comprises a controller comprising:
a pack state of charge (SOC) acquirer configured to acquire SOC values from the respective first and second battery packs at regular intervals,
a system state determiner configured to determine whether the external system is in a standby state and outputs to output a standby state signal if the external system is determined to be in the standby state,
a switch connection determiner configured to determine whether to switch a connection state between the first and second battery packs according to a SOC difference between the first and second battery packs if the standby state signal is output from the system state determiner, and
a switching controller configured to control opening and closing of the first to fifth switches based on the determination by the switch connection determiner.

6. The system of claim 5, wherein:
the switch connection determiner comprises:
a pack SOC difference calculator configured to calculate a pack SOC difference using the SOC values of the respective first and second battery packs acquired by the pack SOC acquirer, if the standby state signal is output, and
a comparison determiner configured to determine whether the calculated pack SOC difference exceeds a predetermined reference pack SOC difference, and to determine that the first and second battery packs are to be switched to a parallel connection if the calculated pack SOC difference exceeds the predetermined reference pack SOC difference, and
the switch connection determiner is further configured to output a parallel switching signal if the comparison determiner determines that the parallel connection switching is to be made.

7. The system of claim 6, wherein:
if the parallel switching signal is output, the switching controller is configured to turn off the third, fourth, and fifth switches to open the third, fourth, and fifth paths, and to turn on the first and second switches to close the first and second paths to connect the first and second battery packs in parallel.

8. The system of claim 7, wherein:
if the pack SOC difference calculated by the pack SOC difference calculator does not exceed the predetermined reference pack SOC difference after the parallel switching signal is output, the comparison determiner is configured to determine that the first and second battery packs are to be switched to be connected in series and configured to output a serial switching signal, and
if the serial switching signal is output, the switching controller is further configured to turn on the third, fourth, and fifth switches to close the third, fourth, and fifth paths, and to turn off the first and second switches to open the first and second paths, thereby connecting the first and second battery packs in series.

9. A battery pack-to-pack charging control method for controlling charging between a plurality of battery packs, including first and second battery packs, the method comprising:
acquiring state of charge (SOC) values of the first and second battery packs, respectively, at regular intervals in an external system;
determining whether the external system is in a standby state; and
connecting the first and second battery packs in parallel according to an SOC difference between the first and second battery packs if the external system is determined as being in the standby state,
wherein the connecting of the first and second battery packs in parallel comprises:
calculating a pack SOC difference using the acquired SOC values of the respective first and second battery packs if the external system is determined as being in the standby state, and
comparing whether the calculated pack SOC difference exceeds a predetermined reference pack SOC difference, and determining that the first and second battery packs are to be switched to a parallel connection if the calculated pack SOC difference exceeds the predetermined reference pack SOC difference.

10. The method of claim 9, wherein the connecting of the first and second battery packs in parallel further comprises:
turning off third, fourth, and fifth switches of a battery connector configured between the first and second battery packs and the external system to open a third, fourth, and fifth paths, and turning on first and second switches to close a first and second paths, thereby connecting the first and second battery packs in parallel.

11. The method of claim 9, further comprising:
determining whether the parallel connection of the first and second battery packs is to be switched to a series connection according to whether the SOC difference between the first and second battery packs is within the predetermined reference pack SOC difference after the parallel connection; and
connecting the first and second battery packs in series if the parallel connection is determined to be switched to the series connection,
wherein the determining of whether the parallel connection is to be switched to the series connection comprises;
calculating the pack SOC difference a second time using the SOC values of the respective first and second battery packs acquired after the parallel connection, and
determining that the parallel connection of the first and second battery packs is to be switched to the series connection if the second calculated pack SOC difference is within the predetermined reference SOC difference.

12. The method of claim 11, wherein the connecting of the first and second battery packs in series comprises:
turning on third, fourth, and fifth switches of a battery connector configured between the first and second battery packs and the external system to close third, fourth, and fifth paths, and turning off first and second switches to open first and second paths to connect the first and second battery packs in series.
